(19) United States
(12) Patent Application Publication
(10) Pub. No.: US 2025/0189900 A1
(43) Pub. Date: Jun. 12, 2025

(54) INTERMEDIATE PRODUCT FOR PRODUCING AN OPTICAL ELEMENT FOR A PROJECTION EXPOSURE APPARATUS, OPTICAL ELEMENT FOR A PROJECTION EXPOSURE APPARATUS, METHOD FOR PRODUCING AN INTERMEDIATE PRODUCT, AND METHOD FOR PRODUCING AN OPTICAL ELEMENT

(71) Applicant: Carl Zeiss SMT GmbH, Oberkochen (DE)

(72) Inventors: Sandro HOFFMANN, Oberkochen (DE); Christoph SCHMITZ, Oberkochen (DE)

(21) Appl. No.: 19/059,808

(22) Filed: Feb. 21, 2025

Related U.S. Application Data
(63) Continuation of application No. PCT/EP2023/071762, filed on Aug. 7, 2023.

(30) Foreign Application Priority Data
Aug. 22, 2022 (DE) 10 2022 208 658.9

(51) Int. Cl. G03F 7/00

(52) U.S. Cl. CPC G03F 7/70316; G03F 7/70233

(57) ABSTRACT

An intermediate product for producing an optical element for a projection exposure apparatus (1) has a substrate (20) for specifying a basic topography of an optical surface, wherein a plurality of etchable layers including a layer (22ᵢ) to be structured and a contrast layer (23ᵢ) are applied to the substrate (20), wherein the layer (22ᵢ) to be structured and the contrast layer (23ᵢ) have different chemical properties such that a removal of the contrast layer (23ᵢ) can be detected in situ.

### CROSS REFERENCE TO RELATED APPLICATIONS

This is a Continuation of International Application PCT/EP2023/071762 which has an international filing date of Aug. 7, 2023, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2022 208 658.9 filed on Aug. 22, 2022.

### FIELD OF THE INVENTION

The invention relates to an intermediate product for producing an optical element for a production exposure apparatus, in particular for producing a mirror for a projection exposure apparatus, in particular an EUV projection exposure apparatus. The invention also relates to an optical element for a projection exposure apparatus, in particular a mirror. Furthermore, the invention relates to a method for producing an intermediate product for producing an optical element for a projection exposure apparatus. Moreover, the invention relates to a method for producing an optical element for a projection exposure apparatus. Finally, the invention relates to an apparatus for producing an optical element for a projection exposure apparatus.

### BACKGROUND

Precisely specifying the surface topography of optical elements for a projection exposure apparatus, in particular mirrors, is important for the production thereof. It is difficult to precisely produce optical elements with an exactly specified surface topography.

### SUMMARY

One object addressed by the invention is that of improving an intermediate product for producing an optical element for a projection exposure apparatus and an optical element produced therefrom.

According to one formulation, this object is addressed by an intermediate product as claimed herein and an optical element produced therefrom.

One aspect of the invention consists of applying a plurality of structurable layers, in particular etchable layers, on a substrate, with at least a subset of these layers serving as contrast layers. This should be understood to mean that the removal of the contrast layers is detectable, in particular detectable in situ.

As a result, structuring of the layer to be structured can be monitored during the structuring process, in particular without needing to interrupt the structuring process. In particular, it is not necessary to measure the intermediate product with separate measuring methods. This significantly improves the production process for the intermediate product and the optical element that can be produced therefrom.

The substrate to which the structurable layers are applied may have a plane surface, in particular a substantially plane surface, in particular a complete plane surface, or a curved surface, in particular a convex or a concave surface. In particular, the substrate may have a surface topography that is describable by a continuously differentiable function. In principle, however, surface topographies with kinks and/or jump discontinuities are also possible.

According to one aspect of the invention, the contrast layer may in particular also comprise an etchable material. In particular, it may consist of an etchable material.

A material is considered to be etchable if a physical and/or chemical removal of the material may be achieved by wet and dry etching methods. To produce a topography, the etching rate of the material in a process may in particular be higher or at least not be significantly lower than the etching rate of an etching mask used here (typically made of oxides, nitrides, or metals (=hard masks) or polymers (=photomasks)).

According to a further aspect, at least 90%, in particular at least 95%, of the different layers, in particular the layer to be structured and the contrast layer, may consist of materials whose etching rates, in particular in a specified etching method, deviate by no more than 10% from one another.

What this may achieve is that the layer to be structured and the contrast layer are structured substantially the same, in particular if they are subjected to the same structuring method.

In particular, the etching method may be a dry etching method, in particular ion etching (RIE, reactive ion etching) or DRIE (deep reactive ion etching) or ion beam etching, in particular reactive ion beam etching (RIBE).

For example, hydrofluorocarbons, CxHyFz (y,x,z being whole numbers including 0) may be used as process gas in dry etching methods for etching silicon or silicon-containing compounds (SiOx; SiNx).

Possible additives of the gas mixture in this case are oxygen, nitrogen and argon.

Acceleration voltages of typically 30 V to 300 V are conventional in RIE, as are 0.5 kV to 2 kV in ion beam etching (RIBE).

What may be exploited here is the fact that parameter windows in which the etching rates of the aforementioned materials do not differ significantly may be found in each case.

According to another aspect, the different layers, in particular the layer to be structured and the contrast layer, may consist of materials whose densities differ by no more than 10%, in particular no more than 5%, in particular no more than 3%, in particular no more than 2%, in particular no more than 1%, from one another.

According to another aspect, the layers may have a correspondingly similar roughening behavior.

According to a further aspect, the contrast layer and the layer to be structured may have a starting material with the same chemical properties, in particular with the same chemical element or the same chemical compound, wherein the starting material of the contrast layer is modified by doping or ion implantation.

In particular, the contrast layer and the layer to be structured may consist of the same starting material, wherein the starting material of the contrast layer is modified, in particular by doping or ion implantation.

The material of the contrast layer may in particular contain at least one additional chemical element or one or more additional chemical compounds.

By preference, all of the contrast layers and/or of the layers to be structured are made from a corresponding starting material with the same chemical properties. In particular, they may consist of the same starting material with the specified modification.

According to a further aspect of the invention, the contrast layer may have a thickness, in particular a maximum thickness, of no more than 10 nm, in particular no more than 5 nm, in particular no more than 3 nm, in particular no more than 2 nm, in particular no more than 1 nm, in particular no more than 0.5 nm.

A lower thickness of the contrast layer may result in higher precision in the production of a specified surface topography.

According to a further aspect of the invention, the layer to be structured may have a thickness in the range of 10 nm to 50 μm. The thickness of the layer to be structured may in particular have at least 20 nm, in particular at least 30 nm, in particular at least 50 nm, in particular at least 100 nm. The thickness of the layer to be structured may in particular be no more than 30 μm, in particular no more than 20 μm, in particular no more than 10 μm, in particular no more than 5 μm, in particular no more than 3 μm, in particular no more than 2 μm, in particular no more than 1 μm.

The ratio of the thickness of the contrast layer to the thickness of the layer to be structured may in particular be in the range of 1:104 to 1:1. In particular, it is at least 1:104, in particular at least 1:103.

In particular, it is no more than 1:1, in particular no more than 1:2, in particular no more than 1:5, in particular no more than 1:10, in particular no more than 1:20; in particular no more than 1:30, in particular no more than 1:50, in particular no more than 1:100, in particular no more than 1:200, in particular no more than 1:300, in particular no more than 1:500, in particular no more than 1:1000.

According to a further aspect of the invention, the intermediate product may comprise a plurality of contrast layers, which form intermediate layers in the layer to be structured. In this context, a contrast layer may also form an intermediate layer between the substrate and the layer to be structured.

The number of contrast layers may be at least 2, in particular at least 3, in particular at least 5, in particular at least 10, in particular at least 20, in particular at least 30, in particular at least 50, in particular at least 100.

A greater number of contrast layers allows for improved monitoring of the structuring process. A smaller number of contrast layers facilitates the production of the intermediate product.

According to a further aspect of the invention, the intermediate product may comprise a plurality of contrast layers, wherein at least two of the contrast layers have different chemical compositions and/or different modifications. In particular, it is possible for at least two of the contrast layers to have different doping or be implanted with different ions.

In particular, it is advantageous if at least two of the contrast layers are formed such that they are unambiguously verifiable through a mass spectroscopic method, in particular via a residual gas analysis.

As a result, one or more of the contrast layers may take the form of special signal layers, which may be used for controlling the structuring method in particular.

It is also possible for all contrast layers to be made of the same material, in particular have the same chemical composition and/or the same modification.

Provision may also be made for all of the contrast layers to have different chemical compositions and/or different modifications.

Provision may also be made for the intermediate product to comprise a single contrast layer, which differs from all other layers, in particular from all other contrast layers, in terms of its chemical composition and/or modification.

Such a unique contrast layer may be used to trigger a special signal, in particular a stop signal.

According to a further aspect of the invention, the intermediate product may comprise a plurality of contrast layers that have different distances between them. In this context, it is possible for only a subset of the contrast layers to have different distances between them. It is also possible for all of the contrast layers to have different distances, in particular in each case pairwise different distances, between them. It is also possible for a subset of the contrast layers, in particular all of the contrast layers, to have the same distances between them.

In particular, provision may be made for the distance between the contrast layers to increase, in particular grow monotonically, in particular grow strictly monotonically, with increasing distance from the substrate.

This may be advantageous for controlling the structuring process. In particular, it has been recognized that increasingly close control of the structuring process may be advantageous as the latter increasingly progresses.

According to a further aspect of the invention, one or more subsets of the contrast layers may form special sequences. To this end, they may have predetermined sequences of their thicknesses and/or distances between them and/or chemical compositions. Such sequences may be used as control signals for controlling the production process, in particular for controlling the structuring of the intermediate product.

According to a further aspect of the invention, one or more of the contrast layers and/or one or more of the layers to be structured have a thickness that varies over their extent.

In this context, the thickness may be measured locally perpendicular to a surface in each case, in particular perpendicular to the front or back side of the respective layer.

In particular, provision may be made for exactly one of the contrast layers and/or the layers to be structured to be formed with a thickness that varies over their extent.

Provision may also be made for all of the contrast layers and/or all of the layers to be structured to have a thickness that varies over their extent.

It is also possible for all of the contrast layers and/or all of the layers to be structured to have a constant thickness over their extent.

According to a further aspect of the invention, the intermediate product may comprise a plurality of contrast layers, wherein at least two of the contrast layers have a distance between them that varies over their extent.

According to a further aspect of the invention, the intermediate product may comprise a plurality of layers to be structured, wherein at least two of the layers to be structured have a distance between them that varies over their extent.

In particular, provision may be made of one or more contrast layers and/or one or more layers to be structured that have a thickness gradient.

This may improve, in particular simplify, the production of specified surface topographies, in particular the production of optical components with specified surface topographies. This may be advantageous, in particular, in the production of optical elements with free-form surfaces.

According to a further aspect of the invention, an optical element for a projection exposure apparatus, in particular an extreme ultraviolet (EUV) projection exposure apparatus, may be produced from the above-described intermediate product.

The optical element may in particular comprise a radiation-reflecting layer, in particular an EUV radiation-reflecting layer. In particular, a double stack, in particular a molybdenum-silicon double stack, may serve as a radiation-reflecting layer.

In particular, the optical element may be a mirror, in particular a mirror with a grating structure. The grating structure may serve as a spectral filter, in particular for suppressing unwanted wavelengths. In particular, the grating may be used to suppress infrared radiation and/or, in the case of an EUV mirror, to suppress deep ultraviolet (DUV) radiation.

In particular, the mirror may be a collector mirror, in particular of a radiation source module of a projection exposure apparatus, a mirror of an illumination optical unit of a projection exposure apparatus, in particular a facet mirror, in particular a single facet, or a mirror of a projection optical unit of a projection exposure apparatus.

The mirror may have a total reflection area of more than 100 cm², in particular more than 200 cm², in particular more than 300 cm², in particular more than 500 cm², in particular more than 1000 cm², in particular more than 2000 cm², in particular more than 3000 cm², in particular more than 5000 cm², in particular more than 10 000 cm². As a rule, the total reflection area of the mirror is less than 10 m². However, this should not be understood to be restrictive.

The optical element may also have a smaller total reflection area.

A further object addressed by the invention consists of improving a method for producing an intermediate product according to the preceding description and a method for producing an optical element for a projection exposure apparatus according to the preceding description.

According to a further formulation, these objects are addressed by methods comprising the following steps:
providing a substrate for specifying a basic topography of an optical surface,
applying a plurality of etchable layers to the substrate, wherein the layers comprise at least one layer to be structured and at least one contrast layer,
wherein the layer to be structured and the contrast layer have different chemical properties such that a removal of the contrast layer can be detected in situ.

The method for producing an optical element moreover comprises the steps of:
structuring the intermediate product and
monitoring the structuring procedure in situ.

The method according to the invention enables the structuring of intermediate products for the production of EUV mirrors with a sufficiently accurate etching rate control while at the same time making high demands on profile fidelity.

In particular, an etching method, in particular a dry etching method, in particular ion etching, in particular reactive ion etching or reactive ion beam etching, is provided for structuring the intermediate product.

In particular, a mass spectroscopic method, in particular a residual gas analysis, may serve for monitoring the structuring procedure in situ.

A radiation-reflecting coating, in particular an EUV radiation-reflecting coating, may be applied to the structured intermediate product.

By providing the contrast layers, the application of which can be reliably verified in situ, the progress of material removal may be spatially and/or temporally monitored with precision. An interruption of the structuring process, as has been required to date for the purpose of determining an already etched step depth, may be omitted.

The overall process duration may be significantly reduced since the structuring process need not be interrupted for monitoring the progress of the same.

The risk of contamination is reduced since the intermediate product need not be removed from the vacuum chamber for control measurements.

Moreover, there is no risk of the mirror surface being modified by contact with atmosphere, which may in particular lead to an undesirable change in the etching rate.

Changes in the process chamber are also reliably prevented.

In particular, it is possible to precisely and reliably monitor the progress of the structuring of the intermediate product during the structuring process, i.e. in situ.

Advantageously, the structuring of the intermediate product may be controlled on the basis of monitoring of the structuring procedure. A feedback loop may be provided to this end. Structuring the intermediate product may therefore be regulated (closed-loop method).

In particular, it is possible to detect a changing etching rate on account of wear or long process duration via the fed-back signals. This may be compensated by e.g. increasing the power in the etching process according to an evaluation of the peak distances in the residual gas analysis.

According to one aspect of the invention, provision may be made for an in-situ analysis of the removed layers to be used for monitoring the structuring procedure, wherein an evaluation of this analysis is used in particular as a control signal for the further structuring procedure.

The in-situ analysis may be used in particular for determining a chemical signal, in particular a chemical fingerprint, of an at least partially removed layer.

In the structuring of the intermediate product, different contrast layers, in particular contrast layers with different chemical compositions and/or with different modifications and/or sequences of contrast layers, in particular with different thicknesses and/or different distances between them and/or different numbers of contrast layers, may serve as a signal transmitter, in particular for different control signals.

The structuring of an intermediate product for producing an optical element for a projection exposure apparatus may take a long time, in particular several hours or even several days, especially in the case of optical elements with a large total reflection area. By targeted arrangement and/or formation of the contrast layers, it is possible in this context to monitor the structuring procedure very precisely without interrupting the structuring procedure in the process, in particular without taking the intermediate product, in particular the possibly already partially structured intermediate product, from a vacuum atmosphere provided for structuring, in particular from a vacuum chamber provided to this end, in particular from an at least partially evacuated vacuum chamber provided to this end.

According to a further aspect of the invention, a roughness-preserving method, in particular a smoothing method, for example a sputtering method, in particular a magnetron sputtering method (MSD, magnetron sputter deposition), a physical or chemical vapor deposition method (PVD, CVD, in particular a plasma-enhanced CVD, PECVD), an atomic layer deposition method (ALD method), a pulsed laser deposition method (PLD method), an ion beam sputtering method, or an electron beam evaporation method, may be provided for applying the layer to be structured and/or for applying the contrast layer.

Such an application method enables a very precise application of layers, in particular an application with a predetermined thickness, in particular a predetermined thickness profile.

According to a further aspect of the invention, the method provided for applying the layers may only comprise roughness-preserving additive steps.

A further object addressed by the invention is that of improving an apparatus for producing an optical element for a production exposure apparatus.

These and other objects are addressed by an apparatus having the following features:
a vacuum chamber for receiving an intermediate product for producing an optical element for a projection exposure apparatus,
a device for structuring the intermediate product in the vacuum chamber,
a device for monitoring the structuring of the intermediate product in situ,
wherein the device for monitoring the structuring of the intermediate product is coupled in data-transmitting fashion with the device for structuring the intermediate product in the vacuum chamber.

In particular, the intermediate product is an intermediate product according to the preceding description.

In particular, the apparatus comprises a control device for controlling the device for structuring the intermediate product.

In particular, a feedback loop may be provided at the device for monitoring the structuring and the device for structuring the intermediate product.

Detection via a residual gas analysis may be implemented with one or more mass spectrometers in particular. The use of a plurality of detectors/measuring devices may increase the accuracy, in particular improve the signal-to-noise ratio.

The choice of mass spectrometers is preferably made such that masses with a higher atomic number can also be detected. This may be matched to the additive material in the signaling layer.

In particular, a plurality of mass spectrometers may be distributed in the chamber such that a spatial distribution of the etching rate may be ascertained (in a manner analogous to triangulation) through an appropriate evaluation of the measurement data at specific chamber pressures. For example, this may be advantageous when calibrating or determining the tool function.

The mass spectrometers may be positioned in the backscatter region of the etched material.

A mass spectrometer may not be positioned directly within the process chamber (spectrometer working pressure is typically ideally 10⁻⁸ mbar to 10⁻⁶ mbar, max. 10⁻⁴ mbar), in particular in the event of higher chamber pressures in the etching process (in particular in the range of 10⁻⁴ mbar to 5·10⁻⁴ mbar). This object is addressed by positioning in a differentially pumped region (secondary chamber), which is only connected to the main process chamber via a pinhole (=gas flow limitation). This region may then be at a lower pressure, and the detected mass ratios remain almost identical.

The invention moreover relates to a collector, an illumination optical unit, an illumination system, a radiation source module and a projection exposure apparatus having an optical component according to the preceding description, and also to a method for producing a nanostructured component and a component produced according to the method.

In principle, one or more etch stop layers may also be specified.

The etch stop layers may differ significantly from the contrast layers. In particular, they may be made of a significantly different material to the structuring layer. In particular, they may have a different etching rate, in particular a significantly lower etching rate, in comparison with the structuring layer. For details, reference should be made to the German patent application DE 10 2020 207 807.9. A combination of contrast layers and etch stop layers may also lead to advantages.

### BRIEF DESCRIPTION OF THE DRAWINGS

Further details and advantages of the invention will become apparent from the description of exemplary embodiments with reference to the figures. In the figures:

FIG. 1 schematically shows a meridional section through a projection exposure apparatus for EUV projection lithography,

FIG. 2 schematically shows a detail from a cross section through an intermediate product for producing an optical element,

FIG. 3 schematically shows a sequence of process steps from the process chain for producing an optical element,

FIG. 4 schematically shows a cross section through an intermediate product for producing an optical component with a curved reflection surface,

FIG. 5 schematically shows a detail from a cross section through an intermediate product for producing an optical element, and

FIG. 6 schematically shows the detail according to FIG. 5 following an exemplary structuring.

### DETAILED DESCRIPTION

Firstly, the general construction of a microlithographic projection exposure apparatus 1 will be described.

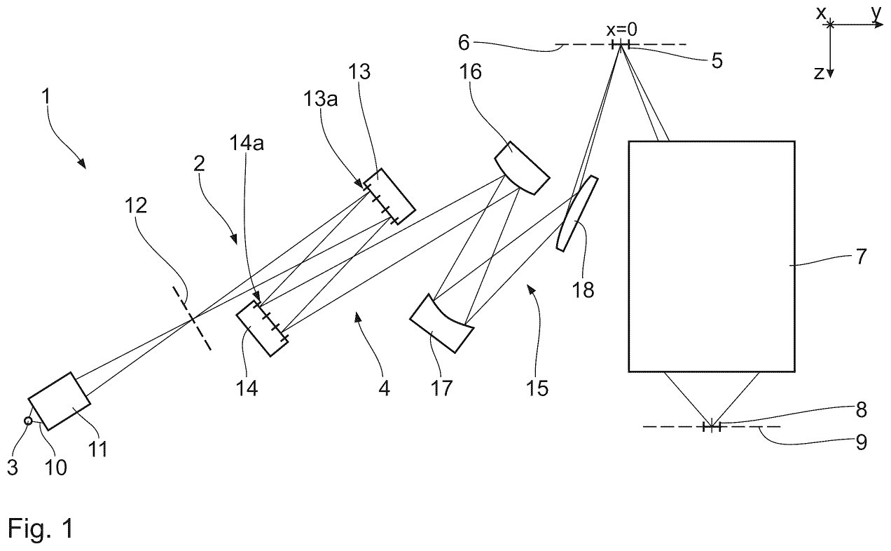

FIG. 1 schematically shows a meridional section of a microlithographic projection exposure apparatus 1. An illumination system 2 of the projection exposure apparatus 1 has, besides a radiation source 3, an illumination optical unit 4 for the exposure of an object field 5 in an object plane 6. In this case, a reticle (not illustrated in the drawing) that is arranged in the object field 5 and is held by a reticle holder (likewise not illustrated) is exposed. A projection optical unit 7 serves for imaging the object field 5 into an image field 8 in an image plane 9. A structure on the reticle is imaged onto a light-sensitive layer of a wafer (likewise not illustrated in the drawing) that is arranged in the region of the image field 8 in the image plane 9 and is held by a wafer holder (likewise not illustrated).

The radiation source 3 is an EUV radiation source with emitted used radiation in the range of between 5 nm and 30 nm. This may be a plasma source, for example a GDPP (gas discharge-produced plasma) source or an LPP (laser-produced plasma) source. For example, tin may be excited to form a plasma with a carbon dioxide laser operating at a wavelength of 10.6 μm, i.e. in the infrared range. A radiation source based on a synchrotron may also be used for the radiation source 3. Information about such a radiation source may be found by the person skilled in the art, for example, in U.S. Pat. No. 6,859,515 B2. EUV radiation 10 emerging from the radiation source 3 is focused by a collector 11. A corresponding collector is known from EP 1 225 481 A. Downstream of the collector 11, the EUV radiation 10 propagates through an intermediate focal plane 12 before being incident on a field facet mirror 13 with a multiplicity of field facets 13a. The field facet mirror 13 is arranged in a plane of the illumination optical unit 4 which is optically conjugate with respect to the object plane 6.

he EUV radiation 10 is also referred to hereinafter as illumination light or as imaging light.

Downstream of the field facet mirror 13, the EUV radiation 10 is reflected by a pupil facet mirror 14 with a multiplicity of pupil facets 14a. The pupil facet mirror 14 is arranged in a pupil plane of the illumination optical unit 4, which is optically conjugate with respect to a pupil plane of the projection optical unit 7. With the aid of the pupil facet mirror 14 and an imaging optical assembly in the form of a transfer optical unit 15 with mirrors 16, 17 and 18 designated in the order of propagation of the beam path, individual field facets, which are also referred to as subfields or as individual mirror groups, of the field facet mirror 13 are imaged into the object field 5. The last mirror 18 of the transfer optical unit 15 is a mirror for grazing incidence (“grazing incidence mirror”).

With the aid of the projection exposure apparatus 1, at least one part of the reticle in the object field 5 is imaged onto a region of a light-sensitive layer on the wafer in the image field 8 for the lithographic production of a microstructured or nanostructured component, in particular of a semiconductor component, for example of a microchip. Depending on the embodiment of the projection exposure apparatus 1 as a scanner or as a stepper, the reticle and the wafer are moved in the y-direction in a manner synchronized in time, continuously in scanner operation or stepwise in stepper operation.

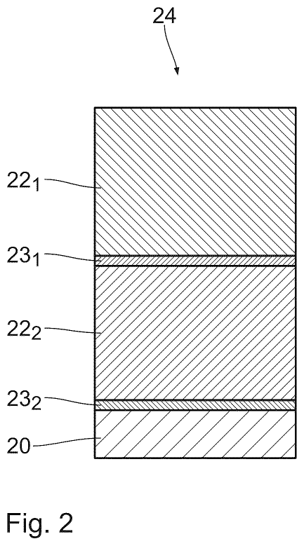

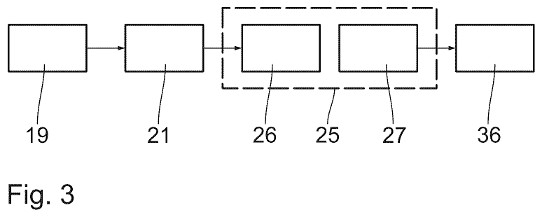

A method for producing an optical element of the projection exposure apparatus 1 and intermediate products in the production of this optical element are described below with reference to FIGS. 2 to 5.

The optical element may in particular be a mirror, in particular a mirror of the illumination optical unit 4 or the projection optical unit 7. In particular, it may be a mirror of the collector 11. It may also be a spectral filter, in particular a filter for suppressing infrared radiation (IR radiation). In particular, it is an EUV-reflecting mirror with an IR-suppressing effect. For further details of such an optical element, reference is made, for example, to PCT/EP 2019/082 407, which is incorporated herein by reference.

First, a substrate 20 is provided in a provision step 19. The substrate 20 is used to specify a basic topography of the optical element. In particular, it may have a non-planar, i.e. a curved, surface. In particular, it may have a convex or concave surface. The substrate may have an aspheric, in particular an ellipsoidal, or a paraboloidal basic topography.

In an application step 21, a sequence of layers 22i (i≥1) to be structured and contrast layers 23i (i≥1) is applied to the substrate 20.

The layers 22i to be structured and the contrast layers 23i may in particular be applied through a deposition method, in particular with a sputtering method, in particular with a magnetron sputtering method (MSD, magnetron sputter deposition) or with a vapor deposition method (PVD, CVD, PECVD) or an atomic layer deposition method (ALD) or a pulsed laser deposition (PLD) method, an ion beam sputtering method or an electron beam evaporation method.

The layers 22i to be structured are applied with a thickness Di. The layer thickness Di may vary over the surface of the substrate 20, Di=Di(s); here, s indicates the position on the surface of the substrate 20. The etching layer 22i is applied to the substrate 20, in particular with a layer thickness Di(s) according to a specified layer thickness profile Div(s).

The layer thickness Di(s), in particular in the region of the entire surface of the substrate 20, deviates by no more than 1% from the specified layer thickness Div(s).

The layers 22i to be structured have a smooth surface. Their surface roughness is in particular 0.15 nm rms. This specification refers in particular to the range of high spatial frequencies, in particular of at least 1/μm.

The layers 22i to be structured have a thickness Di of a few μm in particular. The thickness Di of the layers 22i to be structured may be in the range of 0.1 μm to 12 μm in particular.

The overall thickness of the coating of the substrate 20, in particular the sum of the thickness of all of the layers 22i to be structured and contrast layers 23i, is in particular no more than 100 μm, in particular no more than 50 μm, in particular no more than 30 μm, 20 μm, in particular no more than 10 μm. These specifications should not be understood as limiting.

The layers 22i to be structured for example may be made of crystalline amorphous silicon, SiO2, Si3N4 or other silicon-based compounds.

Their thickness Di is set directly during coating. The thickness Di may be set in particular with an accuracy of better than 1%, in particular better than 0.5%, in particular better than 0.3%, in particular better than 0.2%.

The contrast layers 23i are preferably made of a material with similar etching properties to the layers 22i to be structured. The contrast layers 23i may be made in particular of a material with a comparable etching rate and/or a comparable density and/or a comparable roughening behavior in the same etching process. In this case, comparable properties are understood to mean that the respective parameters differ by no more than 50%, in particular 30%, in particular no more than 20%, in particular no more than 10%, in particular no more than 5%, in particular no more than 3%, in particular no more than 2%, in particular no more than 1%.

The contrast layers 23i may be modified, for example by doping or ion implantation.

The contrast layers 23i have a thickness D in the order of a few nm, in particular in the range from 0.5 nm to 20 nm, in particular up to 10 nm. In particular, they have a maximum surface roughness that corresponds to the surface roughness of the layers 22i to be structured.

The layers 22i to be structured and the contrast layers 23i are applied in particular through a roughness-preserving, in particular a smoothing, process.

They are applied with great precision. The maximum thickness deviation over the optically used surface area of the optical component is in particular no more than 2%, in particular no more than 1%, in particular no more than 0.5%, in particular no more than 0.3%, in particular no more than 0.2%. In the event of a layer thickness of the layer 22i to be structured in the order of a few micrometers, the maximum thickness deviation may be in particular no more than 50 nm, in particular no more than 30 nm, in particular no more than 20 nm, in particular no more than 10 nm. The layers 22i to be structured are therefore also referred to as shape-retaining or shaping layers.

The term shape-retaining layer is used in particular if the layer has a constant thickness. Layers of varying thickness are referred to as shaping layers.

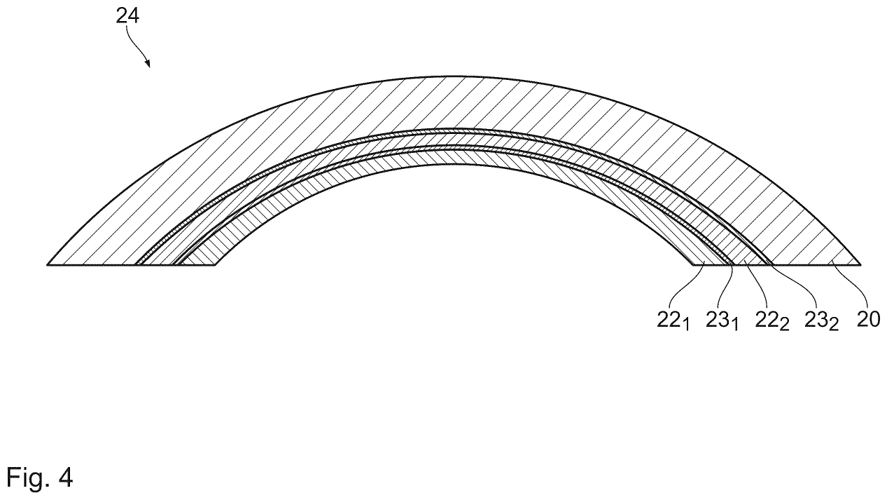

An intermediate product 24 for producing the optical element is available after applying all the layers 22i to be structured and contrast layers 23i onto the substrate 20. FIG. 4 shows an example of an intermediate product 24 for producing a collector shell. In this case, the substrate 20 has a curved surface, in particular an ellipsoidal or a paraboloidal surface.

The layers 22i to be structured are structured in a structuring step 25. A lithography step 26 and a subsequent etching step 27 are provided to this end.

As regards details of the structuring step, reference is made to DE 10 2018 220 629.5.

In a subsequent application step 36, a radiation-reflecting layer is applied. This is not depicted in the figures.

The radiation-reflecting layer is an EUV-radiation-reflecting layer in particular. The radiation-reflecting layer is in particular a layer stack made of molybdenum-silicon double layers.

There may be further possible layers between the radiation-reflecting layer and the shaping layers 22i to be structured. In particular, protective layers or other functional layers may be applied to the layers 22i to be structured, in particular to the uppermost of the layers 22i to be structured.

The radiation-reflecting layer may be applied directly to the uppermost of the layers 22i. Due to the low surface roughness of these layers, a preceding polishing step can be dispensed with.

In principle, the uppermost layer 22i to be structured may also be polished.

The method described above leads to advantages in particular with regard to integral parts of the collector 11, in particular collector shells. This is due to a reduction in step depth error. At the same time, the method according to this aspect of the invention leads to a considerable simplification of the process chain, in particular to a reduction in throughput time. This is due to the bypassing of polishing steps and a possible omission of the etch depth determination.

The removal of the layers 22i to be structured in etching step 27 is monitored, in particular monitored continuously. In particular, reaching the contrast layers 23i is detected in the process.

The contrast layers 23i are introduced as intermediate layers into the layers 22i to be structured, at defined intervals Dn(s) and/or with defined thicknesses Tn(s). In this context, the parameter s specifies the position on the substrate and hence the position on the optical component to be produced therefrom.

The contrast layers 23i may be detected with a mass spectroscopic method, in particular with residual gas analysis, during the removal of these layers, in particular through an etching method. The removal of the contrast layers 23i may be detected in situ, in particular in real time. Should the distance between two contrast layers 23i, 23i+1 be known, the etching rate may be determined from the time between two peaks in the residual gas analysis. This may happen globally, i.e. over the entire intermediate product, or locally.

The accuracy of the etching rate determination may be increased by reducing the distances between successive contrast layers 23i 23i+1.

Provision may be made for the contrast layers 23i to be arranged with increasing distances between them as the distance from the substrate 20 increases. This leads to greater distances between them at the start of the structuring process and to shorter distances toward the end of the process, and hence to greater accuracy.

Provision may be made for one or more of the contrast layers to be provided with a special chemical signature, which signals the attainment of a certain depth during the etching. Such contrast layers 23i may serve as signaling devices, in particular as a stop signal.

In principle, any material which has a sufficiently high etching rate in the utilized etching process and which is detectable with sufficient precision through mass spectroscopic methods is possible as material for the contrast layers 23i. Advantageously, the contrast layers 23i are made of a similar material, in particular of the same material, as the layers 22i to be structured. However, they differ from the material of the layers 22i to be structured, for example by a doping or an ion implantation.

For example, contrast in the contrast layers 23i may be established by PVD methods, in which silicon targets or silicon-filled crucibles are used, wherein the targets/crucibles are doped with phosphorus for the production of the contrast layers 23i. Contrast may also be produced by ion implantation or by using a material that has a different chemical composition to that of the layers 22i to be structured but has a similar etching behavior.

The arrangement of the contrast layers 23i between the layers 22i to be structured may have a gradient. This allows locally varying etching rates, such as those that may be provided for curved optical units for example, to be taken into account in a targeted manner.

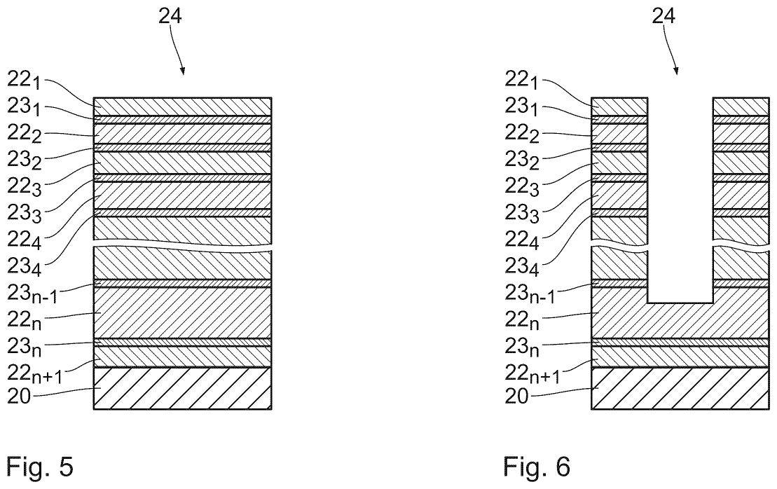

In FIG. 5, a detail of a cross section through an intermediate product 24 with a sequence of layers 22i to be structured and contrast layers 23i is shown as an example. In this case, the contrast layers 23i have an increasing distance between them as the distance from the substrate 20 increases.

In FIG. 6, the state of the intermediate product 24 according to FIG. 5 is shown as an example following a local removal of layers 22i to be structured and contrast layers 23i. The etching depth may be determined from the number of contrast layers removed.

In the following text, different aspects of the invention are described again in the form of keywords. These aspects respectively lead to advantages individually or in combination.

A shape-retaining or a shaping method is used to deposit the layers 22i to be structured. The layers 22i to be structured are therefore also referred to as shaping layers.

A deposition method, in particular a roughness-preserving, preferably smoothing, deposition method is used in particular to apply the shaping layers. The layers thus have a specified layer thickness profile and a very low surface roughness immediately after their application.

An ion beam method, in particular a reactive ion beam method, a plasma method, in particular a reactive plasma method, a plasma jet method, a remote plasma method, atomic layer etching, in particular spatial atomic layer etching, electron beam-assisted etching or another method may be used for selectively removing individual regions of the layers 22i to be structured and/or of the contrast layers 23i, in particular for removing and/or for smoothing these layers. Spatial atomic layer processing or processing with a focused electron beam may also be provided.

The above description of the various embodiments has been given by way of example. From the disclosure given, those skilled in the art will not only understand the present invention and its attendant advantages, but will also find apparent various changes and modifications to the structures and methods disclosed. The applicant seeks, therefore, to cover all such changes and modifications as fall within the spirit and scope of the invention, as defined by the appended claims, and equivalents thereof.

What is claimed is:

1. An intermediate product for producing an optical element for a projection exposure apparatus, comprising:
a substrate for specifying a basic topography of an optical surface, and
a plurality of etchable layers comprising a layer to be structured and a contrast layer applied to the substrate,
wherein the layer to be structured and the contrast layer have differing chemical properties such that a removal of the contrast layer can be detected in situ.

2. The intermediate product as claimed in claim 1, wherein the etchable layers consist of materials whose etching rates in a specified etching method deviate by no more than 10% from one another.

3. The intermediate product as claimed in claim 1, wherein the etchable layers consist of materials having densities differing by no more than 10% from one another.

4. The intermediate product as claimed in claim 1, wherein the contrast layer and the layer to be structured each have a starting material with the same chemical element or the same chemical compound, wherein the starting material of the contrast layer is modified by doping or ion implantation.

5. The intermediate product as claimed in claim 1, wherein the contrast layer has a thickness of no more than 10 nm.

6. The intermediate product as claimed in claim 1, wherein the layer to be structured has a thickness ranging from 10 nm to 50 μm.

7. The intermediate product as claimed in claim 1, further comprising at least one further layer to be structured and at least one further contrast layer that forms an intermediate layer between the layers to be structured.

8. The intermediate product as claimed in claim 1, further comprising at least one further contrast layer, wherein the contrast layers have mutually differing chemical compositions and/or mutually differing modifications.

9. The intermediate product as claimed in claim 1, further comprising at least two further contrast layers, wherein the contrast layers are separated by differing mutual distances.

10. The intermediate product as claimed in claim 1, wherein the contrast layer and/or the layer to be structured have an arealy varying thickness.

11. An optical element for a projection exposure apparatus, produced from an intermediate product as claimed in claim 1.

12. A method for producing an intermediate product as claimed in claim 1, comprising:
providing a substrate for specifying a basic topography of an optical surface,
applying a plurality of etchable layers to the substrate, wherein the layers comprise at least one layer to be structured and at least one contrast layer,
wherein the layer to be structured and the contrast layer have mutually differing chemical properties such that a removal of the contrast layer can be detected in situ.

13. A method for producing an optical element for a projection exposure apparatus, comprising:
providing an intermediate product as claimed in claim 1,
structuring the intermediate product, and
monitoring said structuring in situ.

14. The method as claimed in claim 13, wherein said monitoring of said structuring comprises an in-situ analysis of the removed layer, and wherein an evaluation of the analysis provides a control signal for said structuring procedure.

15. An apparatus for producing an optical element for a projection exposure apparatus, comprising:
a vacuum chamber for receiving an intermediate product for producing an optical element for a projection exposure apparatus,
a device for structuring the intermediate product in the vacuum chamber, and
a device for monitoring the structuring of the intermediate product in situ,
wherein the device for monitoring the structuring of the intermediate product is coupled to and configured to transmit data to the device for structuring the intermediate product in the vacuum chamber.
